(19) United States
(12) Patent Application Publication
(10) Pub. No.: US 2025/0349766 A1
(43) Pub. Date: Nov. 13, 2025

(54) SEMICONDUCTOR PACKAGE AND METHOD FOR MANUFACTURING THE SAME

(71) Applicant: Samsung Electronics Co., Ltd., Suwon-si (KR)

(72) Inventor: Hyung Jun KIM, Suwon-si (KR)

(21) Appl. No.: 18/948,591

(22) Filed: Nov. 15, 2024

(30) Foreign Application Priority Data
May 9, 2024 (KR) 10-2024-0061253

(51) Int. Cl. H01L 23/00; C09D 151/00; H01L 25/065

(52) U.S. Cl. CPC H01L 24/05; H01L 24/32; H01L 24/80; H01L 25/0657; C09D 151/003; H01L 2224/05647; H01L 2224/32225; H01L 2224/80359; H01L 2224/80895; H01L 2225/06582; H01L 2924/13091

(57) ABSTRACT

Provided is a semiconductor package including a lower structure, an upper structure on the lower structure, and a first interfacial layer interposed between the lower structure and the upper structure. The lower structure includes a first semiconductor substrate, a first pad on the first semiconductor substrate, and a first insulating layer surrounding the first pad on the first semiconductor substrate. The upper structure includes a second semiconductor substrate, a second pad on the second semiconductor substrate, and a second insulating layer surrounding the second pad on the second semiconductor substrate. The first interfacial layer includes a first self-assembled monolayer bonded to the first insulating layer, and a second self-assembled monolayer bonded to the second insulating layer.

### CROSS-REFERENCE TO RELATED APPLICATIONS

This U.S. non-provisional patent application claims priority under 35 U.S.C. § 119 of Korean Patent Application No. 10-2024-0061253, filed on May 9, 2024, the entire contents of which are hereby incorporated by reference in its entirety.

### BACKGROUND

The present disclosure herein relates to a semiconductor package and a method for manufacturing the same, and particularly, to a directly bonded semiconductor package and a method for manufacturing the same.

In the semiconductor industry, as demand for high capacity, thinness, and miniaturization of a semiconductor package and an electronic product using the same increases, various package technologies related thereto are emerging. For example, a package technology in which a high-density chip stack may be achieved by vertically stacking various semiconductor chips. This technology may have semiconductor chips having various functions integrated in a smaller area than a general package of one semiconductor chip.

The semiconductor package includes an integrated circuit chip implemented in a form suitable to use in the electronic product. In general, the semiconductor package is implemented by mounting the semiconductor chip on a printed circuit board, and electrically connecting the same by using a bonding wire or a bump. With development of the electronics industry, research for improving reliability and durability of the semiconductor package is variously being conducted.

### SUMMARY

The present disclosure provides a semiconductor package with improved structural stability and a method for manufacturing the same.

The present disclosure also provides a semiconductor package with a good electrical connection between semiconductor chips and a method for manufacturing the same.

The present disclosure also provides a method for manufacturing a semiconductor package with fewer defects and a semiconductor package manufactured thereby.

Some embodiments of the inventive concept provide a semiconductor package including a lower structure, an upper structure on the lower structure, and a first interfacial layer between the lower structure and the upper structure, wherein the lower structure includes a first semiconductor substrate, a first pad on the first semiconductor substrate, and a first insulating layer surrounding the first pad on the first semiconductor substrate, the upper structure includes a second semiconductor substrate, a second pad on the second semiconductor substrate, and a second insulating layer surrounding the second pad on the second semiconductor substrate, and the first interfacial layer includes a first self-assembled monolayer bonded to the first insulating layer, and a second self-assembled monolayer bonded to the second insulating layer.

In some embodiments of the inventive concept, a semiconductor package includes a first semiconductor substrate, a second semiconductor substrate disposed on the first semiconductor substrate, a first insulating layer disposed on a first surface of the first semiconductor substrate facing the second semiconductor substrate, a second insulating layer disposed on a second surface of the second semiconductor substrate facing the first semiconductor substrate, and a first interfacial layer between the first insulating layer and the second insulating layer, wherein the first interfacial layer includes a first head group chemisorbed to a first surface of the first insulating layer, a second head group chemisorbed to a second surface of the second insulating layer, a terminal group between the first head group and the second head group, a first hydrocarbon chain connecting the first head group and the terminal group, and a second hydrocarbon chain connecting the second head group and the terminal group.

In some embodiments of the inventive concept, a method for manufacturing a semiconductor package includes forming, on a first semiconductor substrate, a first pad, and a first insulating layer surrounding the first pad, performing a first surface treatment process on a first surface of the first insulating layer, the first surface treatment process forming a first functional group on the first surface, forming a first self-assembled monolayer on the first surface of the first insulating layer, the first self-assembled monolayer having a first head group bonded to the first functional group, forming, on a second semiconductor substrate, a second pad, and a second insulating layer surrounding the second pad, performing a second surface treatment process on a second surface of the second insulating layer, the second surface treatment process forming a second functional group on the second surface, forming a second self-assembled monolayer on the second surface of the second insulating layer, the second self-assembled monolayer having a second head group bonded to the second functional group, and forming an interfacial layer between the first insulating layer and the second insulating layer by bonding the first self-assembled monolayer and the second self-assembled monolayer.

### BRIEF DESCRIPTION OF THE FIGURES

In the drawings:

FIG. 1 is a cross-sectional view for describing a semiconductor package according to embodiments of the inventive concept;

FIG. 2 is an enlarged diagram illustrating region A of FIG. 1;

FIG. 3 is a conceptual view for exemplarily describing self-assembled monolayers in a first interfacial layer;

FIG. 4 is a conceptual view for describing a first interfacial layer according to an embodiment;

FIG. 5 is a conceptual view for exemplarily describing self-assembled monolayers in a first interfacial layer;

FIG. 6 is an enlarged diagram illustrating region A of FIG. 1;

FIG. 7 is a cross-sectional view for describing a semiconductor package according to embodiments of the inventive concept;

FIG. 8 is a cross-sectional view for describing a semiconductor module according to embodiments of the inventive concept;

FIGS. 9A to 12A are cross-sectional views for describing a method for manufacturing a semiconductor package according to embodiments of the inventive concept;

FIGS. 9B to 12B are conceptual views for describing some embodiments of a first interfacial layer in a method for manufacturing a semiconductor package according to embodiments of the inventive concept; and

FIGS. 13 to 15 are cross-sectional views for describing a method for manufacturing a semiconductor package according to embodiments of the inventive concept.

### DETAILED DESCRIPTION

A semiconductor package according to the inventive concept will be described with reference to the drawings.

Items described in the singular herein may be provided in plural, as can be seen, for example, in the drawings. Thus, the description of a single item that is provided in plural should be understood to be applicable to the remaining plurality of items unless context indicates otherwise.

It will be understood that when an element is referred to as being “connected” to or “on” another element, it can be directly connected to or on the other element or intervening elements may be present. In contrast, when an element is referred to as being “directly connected” to another element, or as “contacting” or “in contact with” another element (or using any form of the word “contact”), there are no intervening elements present at the point of contact.

Spatially relative terms, such as “upper,” “lower” and the like, may be used herein for ease of description to describe positional relationships, such as illustrated in the figures, for example. It will be understood that the spatially relative terms encompass different orientations of the device in addition to the orientation depicted in the figures.

It will be understood that, although the terms first, second, third, fourth, etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention.

As used herein, the words “surrounding” and “surrounded” are intended to mean that an element is around the other element. The elements may be touching or not. The surrounding element may or may not completely surround an inner element. For example, the surrounding element may surround an inner element on the sides of the inner element, but not on the top and/or bottom of the inner element, which is referred to herein as “planarly surrounding” or surrounding from a “plan view”.

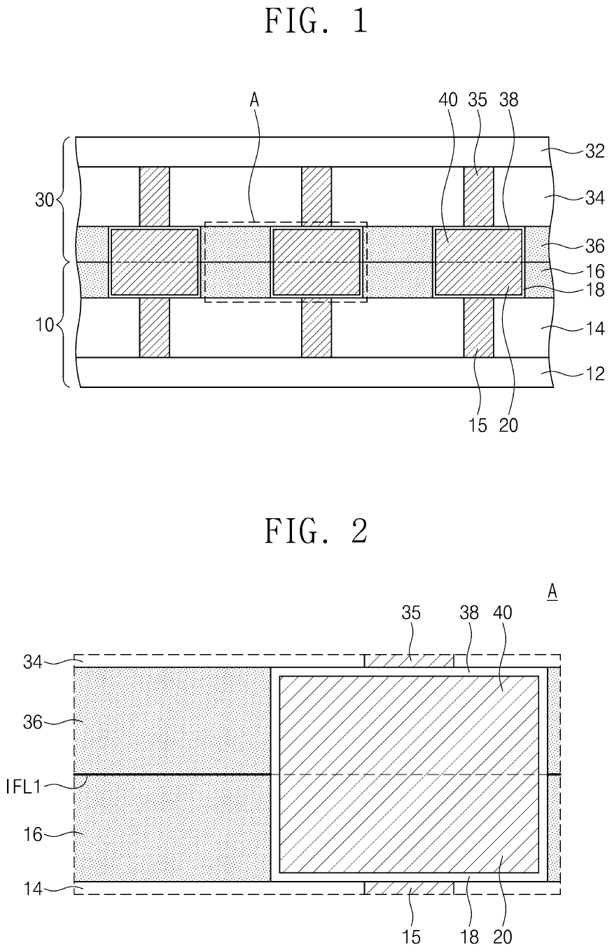

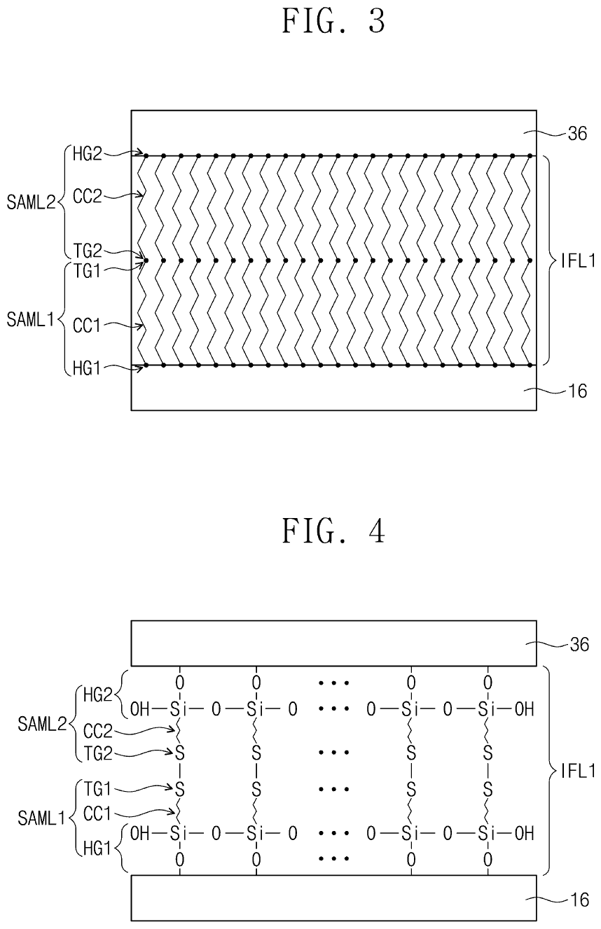

FIG. 1 is a cross-sectional view for describing the semiconductor package according to embodiments of the inventive concept. FIG. 2 is an enlarged diagram illustrating region A of FIG. 1. FIG. 3 is a conceptual view for exemplarily describing self-assembled monolayers in a first interfacial layer.

Referring to FIGS. 1 and 2, the semiconductor package may include a lower structure 10 and an upper structure 30 stacked on the lower structure 10.

The lower structure 10 may include a first substrate 12, a first circuit layer 14, a first insulating layer 16, and first pads 20.

The first substrate 12 may be a semiconductor substrate such as a semiconductor wafer. The first substrate 12 may be a bulk silicon substrate, a silicon-on-insulator (SOI) substrate, a germanium (Ge) substrate, a germanium-on-insulator (GOI) substrate, a silicon-germanium (SiGe) substrate, or an epitaxial thin-film substrate obtained by performing selective epitaxial growth (SEG). For example, the first substrate 12 may include or may be at least one of silicon (Si), germanium (Ge), silicon-germanium (SiGe), gallium arsenide (GaAs), indium-gallium arsenide (InGaAs), aluminum-gallium arsenide (AlGaAs), or a mixture thereof. According to some embodiments, the first substrate 12 may be an insulating substrate such as a printed circuit board (PCB).

The first circuit layer 14 may be on the first substrate 12. The first circuit layer 14 may be disposed on an upper surface of the first substrate 12. The first circuit layer 14 may include a first circuit pattern provided on the first substrate 12, and a first interlayer insulating layer covering the first circuit pattern. The first circuit pattern may be a memory circuit, a logic circuit, or a combination thereof that includes one or more transistors. According to some embodiments, the first circuit pattern may include a passive element such as a resistor, an inductor, or a capacitor.

The first pads 20 may be disposed on the first circuit layer 14. The first pads 20 may be conductive pads disposed on an upper surface of the first circuit layer 14. The first pads 20 may include signal pads electrically connected to the first circuit pattern of the first circuit layer 14, or dummy pads electrically floated in the lower structure 10.

The first pads 20 may have substantially uniform thicknesses. For example, the first pads 20 may have plate shapes. According to other embodiments, unlike what is illustrated in FIGS. 1 and 2, the first pads 20 may each have a T-shaped cross-section including a via portion and a pad portion on the via portion integrally connected to each other. Widths of the first pads 20 may be constant with respect to one another, according to distances from the first substrate 12. According to some embodiments, the widths of the first pads 20 may become smaller toward the first substrate 12. An arrangement of the first pads 20 may be a square arrangement or a honeycomb arrangement, but the inventive concept is not limited thereto. According to some embodiments, a planar shape (e.g. a shape from above) of each of the first pads 20 may be a circle. According to some embodiments, the planar shape of each of the first pads 20 may be a tetragon, an octagon, or a polygon. However, the inventive concept is not limited thereto. According to some embodiments, the planar shape of each of the first pads 20 may vary, as needed. The first pads 20 may include or may be a metal material. For example, the first pads 20 may include or may be copper (Cu).

When the first pads 20 are the signal pads, the first pads 20 may be electrically connected to the first circuit pattern of the first circuit layer 14. For example, as illustrated in FIG. 1, a first connection line 15 may be provided in the first circuit layer 14. The first connection line 15 may be a through via vertically penetrating the first interlayer insulating layer in the first circuit layer 14. The first connection line 15 may vertically extend in the first circuit layer 14 to be connected to the first pads 20. The first connection line 15 may electrically connect the first circuit pattern and the first pads 20. When the first pads 20 are the dummy pads, the first connection line 15 may not be connected to the first pads 20. Although not shown in FIG. 1, various conductive patterns for lining may be provided between the first circuit pattern and the first connection line 15. Unlike what is illustrated in FIG. 1, the first connection line 15 may be an under-pad pattern or redistribution pattern provided in an insulating pattern in the first circuit layer 14. In this case, various conductive patterns for lining may be provided between the first circuit pattern and the first connection line 15, but the inventive concept is not limited thereto. The first circuit layer 14 may be provided in various forms as needed, and the first pads 20 and the first circuit layer 14 may be electrically connected to each other through various configurations as needed.

The first insulating layer 16 may be disposed on the first circuit layer 14. The first insulating layer 16 may surround the first pads 20 on the upper surface of the first circuit layer 14. Upper surfaces of the first pads 20 may be exposed by the first insulating layer 16. For example, the first insulating layer 16 may surround the first pads 20 in a plan view, but may not cover the first pads 20. An upper surface of the first insulating layer 16 and upper surfaces of the first pads 20 may be substantially coplanar with each other. The first insulating layer 16 may include or may be an oxide, a nitride, or an oxynitride of a material that constitutes the first substrate 12 or the first circuit layer 14. The first insulating layer 16 may include or may be for example, an insulating material such as silicon oxide (SiO), silicon nitride (SiN), silicon oxynitride (SiON), or silicon carbonitride (SiCN). For example, the first insulating layer 16 may include or may be silicon oxide (SiO).

The first pads 20 may have a damascene structure in the first insulating layer 16. For example, each of the first pads 20 may further include first seed/barrier patterns 18 covering side surfaces and lower surfaces of the first pads 20. The first seed/barrier patterns 18 may conformally cover the side surfaces and the lower surfaces of the first pads 20. The first seed/barrier patterns 18 may be interposed between the first pads 20 and the first insulating layer 16 and between the first pads 20 and the first circuit layer 14. When the first seed/barrier patterns 18 are used as seed patterns, the first seed/barrier patterns 18 may include metal such as gold (Au). When the first seed/barrier patterns 18 are used as barrier patterns, the first seed/barrier patterns 18 may include or may be metal such as titanium (Ti) or tantalum (Ta), or a metal nitride such as titanium nitride (TiN) or tantalum nitride (TaN).

According to example embodiments, the lower structure 10 includes a first semiconductor substrate 12, a first pad 20 on the first semiconductor substrate 12 and a first insulating layer 16 surrounding the first pad 20 on the first semiconductor substrate 12. It should be understood that components described as being “on the first semiconductor substrate 12”, may have elements therebetween, such as the first circuit layer 14 and the first connection line 15.

The upper structure 30 may be provided on the lower structure 10. The upper structure 30 may include a second substrate 32, a second circuit layer 34, a second insulating layer 36, and second pads 40.

The second substrate 32 may be a semiconductor substrate such as a semiconductor wafer. The second substrate 32 may be a bulk silicon substrate, a silicon-on-insulator (SOI) substrate, a germanium (Ge) substrate, a germanium-on-insulator (GOI) substrate, a silicon-germanium (SiGe) substrate, or an epitaxial thin-film substrate obtained by performing selective epitaxial growth (SEG). For example, the second substrate 32 may include or may be at least one of silicon (Si), germanium (Ge), silicon-germanium (SiGe), gallium arsenide (GaAs), indium-gallium arsenide (InGaAs), or aluminum-gallium arsenide (AlGaAs), or a mixture thereof. According to some embodiments, the second substrate 32 may be an insulating substrate such as a printed circuit board (PCB).

The second circuit layer 34 may be provided under the second substrate 32. The second circuit layer 34 may be disposed on a lower surface of the second substrate 32. The second circuit layer 34 may include a second circuit pattern provided under the second substrate 32, and a second interlayer insulating layer covering the second circuit pattern. The second circuit pattern may be a memory circuit, a logic circuit, or a combination thereof that includes one or more transistors. According to some embodiments, the second circuit pattern may include a passive element such as a resistor, an inductor, or a capacitor.

The second pads 40 may be disposed on the second circuit layer 34. The second pads 40 may be conductive pads disposed on a surface of the second circuit layer 34. The second pads 40 may include signal pads electrically connected to the second circuit pattern of the second circuit layer 34, or dummy pads electrically floated in the upper structure 30.

The second pads 40 may have substantially uniform thicknesses. For example, the second pads 40 may have plate shapes. According to other embodiments, unlike what is illustrated in FIGS. 1 and 2, the second pads 40 may each have a T-shaped (or inverted T-shaped) cross-section including a via portion and a pad portion on the via portion integrally connected to each other. Widths of the second pads 40 may be constant with respect to one another, according to distances from the second substrate 32. According to some embodiments, the widths of the second pads 40 may become smaller toward the second substrate 32. An arrangement of the second pads 40 may be a square arrangement or a honeycomb arrangement, but the inventive concept is not limited thereto. A planar shape of each of the second pads 40 may be a circle. According to some embodiments, the planar shape of each of the second pads 40 may be a tetragon, an octagon, or a polygon. However, the inventive concept is not limited thereto, and the planar shape of each of the second pads 40 may vary as needed. The second pads 40 may include or may be a metal material. For example, the second pads 40 may include or may be copper (Cu).

When the second pads 40 are the signal pads, the second pads 40 may be electrically connected to the second circuit pattern of the second circuit layer 34. For example, as illustrated in FIG. 1, a second connection line 35 may be provided in the second circuit layer 34. The second connection line 35 may be a through via vertically penetrating the second interlayer insulating layer in the second circuit layer 34. The second connection line 35 may vertically extend in the second circuit layer 34 to be connected to the second pads 40. The second connection line 35 may electrically connect the second circuit pattern and the second pads 40. When the second pads 40 are the dummy pads, the second connection line 35 may not be connected to the second pads 40. Although not shown in FIG. 1, various conductive patterns for lining may be provided between the second circuit pattern and the second connection line 35. Unlike what is illustrated in FIG. 1, the second connection line 35 may be an under-pad pattern or redistribution pattern provided in an insulating pattern in the second circuit layer 34. In this case, various conductive patterns for lining may be provided between the second circuit pattern and the second connection line 35, but the inventive concept is not limited thereto. The second circuit layer 34 may be provided in various forms as needed, and the second pads 40 and the second circuit layer 34 may be electrically connected to each other through various configurations as needed.

The second insulating layer 36 may be disposed under the second circuit layer 34. The second insulating layer 36 may surround the second pads 40 on a lower surface of the second circuit layer 34. Lower surfaces of the second pads 40 may be exposed by the second insulating layer 36. For example, the second insulating layer 36 may surround the second pads 40 in a plan view, but may not cover the second pads 40. The upper surface of the second insulating layer 36 and the upper surfaces of the second pads 40 may be substantially coplanar with each other. The second insulating layer 36 may include or may be an oxide, a nitride, or an oxynitride of a material that constitutes the second substrate 32 or the second circuit layer 34. The second insulating layer 36 may include or may be an insulating material such as silicon oxide (SiO), silicon nitride (SiN), silicon oxynitride (SiON) or silicon carbonitride (SiCN). For example, the second insulating layer 36 may include or may be silicon oxide (SiO).

The second pads 40 may have a damascene structure in the second insulating layer 36. For example, each of the second pads 40 may further include second seed/barrier patterns 38 covering side surfaces and lower surfaces of the second pads 40. The second seed/barrier patterns 38 may conformally cover the side surfaces and lower surfaces of the second pads 40. The second seed/barrier patterns 38 may be interposed between the second pads 40 and the second insulating layer 36 and between the second pads 40 and the second circuit layer 34. When the second seed/barrier patterns 38 are used as seed patterns, the second seed/barrier patterns 38 may include or may be metal such as gold (Au). When the second seed/barrier patterns 38 are used as barrier patterns, the second seed/barrier patterns 38 may include or may be metal such as titanium (Ti) or tantalum (Ta), or a metal nitride such as titanium nitride (TiN) or tantalum nitride (TaN).

According to example embodiments, the upper structure 30 includes a second semiconductor substrate 32, a second pad 40 on the second semiconductor substrate 32 and a second insulating layer 36 surrounding the second pad 40 on the second semiconductor substrate 32. It should be understood that components described as being “on the second semiconductor substrate 32”, may have elements therebetween, such as the second circuit layer 34 and the second connection line 35.

The upper structure 30 may be disposed on the lower structure 10. The first pads 20 of the lower structure 10 and the second pads 40 of the upper structure 30 may be vertically aligned with each other. The lower structure 10 and the upper structure 30 may be in contact with each other.

The upper structure 30 may be connected to the lower structure 10. For example, the lower structure 10 and the upper structure 30 may be in contact with each other. The first pads 20 of the lower structure 10 and the second pads 40 of the upper structure 30 may be electrically connected to each other.

The upper structure 30 may be connected to the lower structure 10. For example, the lower structure 10 and the upper structure 30 may be in contact with each other. At an interface of the lower structure 10 and the upper structure 30, the first pads 20 of the lower structure 10 and the second pads 40 of the upper structure 30 may be bonded to each other. In this case, the first pads 20 and the second pads 40 may form an intermetallic hybrid bonding. As used herein, “hybrid bonding” means that two components including the same type of material bond at an interface thereof. For example, the first pads 20 and the second pads 40 bonded to each other may have a continuous configuration, and a boundary surface between the first pads 20 and the second pads 40 may not be visualized. For example, the first pads 20 and the second pads 40 may be composed of the same material, and there may be no interface between the first pads 20 and the second pads 40. For example, the first pads 20 and the second pads 40 may be provided as one component. For example, the first pads 20 and the second pads 40 may be bonded to each other, such that they are integrally formed. For example, when the first pads 20 and the second pads 40 are bonded to each other and integrally formed, they may form hybrid pads that includes both the first pads 20 and the second pads 40.

At the interface of the lower structure 10 and the upper structure 30, the first insulating layer 16 of the lower structure 10 and the second insulating layer 36 of the upper structure 30 may be bonded to each other.

Referring to FIGS. 2 and 3, a first interfacial layer IFL1 may be interposed between the first insulating layer 16 and the second insulating layer 36. The first interfacial layer IFL1 may connect the first insulating layer 16 and the second insulating layer 36. The first interfacial layer IFL1 may be chemically bonded to a surface of the first insulating layer 16. The first interfacial layer IFL1 may be chemically bonded to a surface of the second insulating layer 36. The first insulating layer 16 and the second insulating layer 36 may be firmly bonded to each other through the first interfacial layer IFL1. The first interfacial layer IFL1 may be in contact with the upper surface of the first insulating layer 16. The first interfacial layer IFL1 may be in contact with a lower surface of the second insulating layer 36. The first interfacial layer IFL1 may be spaced apart from first and second pads 20 and 40.

The first interfacial layer IFL1 may include a first self-assembled monolayer SAML1 connected to the first insulating layer 16 and a second self-assembled monolayer SAML2 connected to the second insulating layer 36. Configurations of the first self-assembled monolayer SAML1 and the second self-assembled monolayer SAML2 will be described in greater detail herein.

The first self-assembled monolayer SAML1 may include a first head group HG1, a first terminal group TG1, and a first chain CC1 that connects the first head group HG1 and the first terminal group TG1. The first head group HG1 and the first terminal group TG1 may be functional groups connected to both ends of the first chain CC1. For example, the first self-assembled monolayer SAML1 may be represented as the following Formula 1.

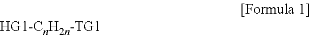

Here, n may be an integer equal to or greater than 1. HG1 represents a functional group (or reaction group) corresponding to the first head group HG1, and TG1 represents a functional group (or reaction group) corresponding to the first terminal group TG1.

The first head group HG1 may include a functional group that reacts with the first insulating layer 16. For example, the first head group HG1 may include a functional group bonded to a hydroxy group (—OH) formed on a surface of the first insulating layer 16. For example, the first head group HG1 may include a hydroxy functional group, a sulfhydryl group/thiol group (—SH), an amino functional group (—NH2), an epoxy functional group, a methoxy functional group (—OCH3), an ethoxy group (—OCH2CH3), or a silane functional group (—Si—X3). The first head group HG1 may be chemisorbed to the surface of the first insulating layer 16. In the present specification, functional groups capable of being provided as the first head group HG1 are exemplarily proposed, but the inventive concept is not limited thereto. The first head group HG1 may include a hydroxy functional group or various functional groups capable of being chemisorbed to the surface of the first insulating layer 16. In addition, in the present specification, it is described that the first self-assembled monolayer SAML1 includes the first head group HG1, but the first head group HG1 of the first self-assembled monolayer SAML1 may be provided in a form in which the first head group HG1 of the first self-assembled monolayer SAML1 is chemisorbed to the surface of the first insulating layer 16. For example, the first head group HG1 may be provided in a form in which functional groups other than the exemplarily proposed functional groups, are chemically bonded to the surface of the first insulating layer 16.

According to example embodiments, the first chain CC1 may include a hydrocarbon chain. A length of the first chain CC1, for example, a length of the hydrocarbon chain may vary as needed.

The first terminal group TG1 may include a functional group that reacts with a second terminal group TG2 of a second self-assembled monolayer SAML2. This will be described together with the second self-assembled monolayer SAML2 in detail.

The first self-assembled monolayer SAML1 may include a silane coupling agent (SCA) based self-assembled monolayer. For example, the first self-assembled monolayer SAML1 may include N-(2-aminoethyl) (3-aminopropyl)methyldimethoxysilane, (3-aminopropyl)triethoxysilane, or (3-aminopropyl) trimethoxysilane with an amino functional group (—NH2). According to some embodiments, the first self-assembled monolayer SAML1 may include vinyltrimethoxysilane or vinyltriethoxysilane with a vinyl functional group (—CH═CH2). According to some embodiments, the first self-assembled monolayer SAML1 may include 3-methacryloxypropyltrimethoxysilane with a methacryloxy functional group. According to some embodiments, the first self-assembled monolayer SAML1 may have 3-glycidoxypropyltrimethoxysilane or 2-(3,4-epoxycyclohexyl)ethyltrimethoxysilane with an epoxy functional group. According to some embodiments, the first self-assembled monolayer SAML1 may include 3-mercaptopropyltrimethoxysilane with a mercapto functional group. According to some embodiments, the first self-assembled monolayer SAML1 may include 3-isocyanatopropyltrimethoxysilane with an isocyanate functional group. According to some embodiments, the first self-assembled monolayer SAML1 may include 1,3,5-tris-(trimethoxysilylpropyl) isocyanurate with an isocyanurate functional group. According to some embodiments, the first self-assembled monolayer SAML1 may include or may be (3-chloropropyl) trimethoxysilane with a chloro functional group. However, the inventive concept is not limited thereto, and the first self-assembled monolayer SAML1 may include various self-assembled monolayers bondable to the surface of the first insulating layer 16. The first self-assembled monolayer SAML1 is described based on one molecule, but the inventive concept is not limited thereto. The first self-assembled monolayer SAML1 may include a plurality of molecules that constitute the self-assembled monolayer.

The second self-assembled monolayer SAML2 may include a second head group HG2, a second terminal group TG2, and a second chain CC2 that connects the second head group HG2 and the second terminal group TG2. The second head group HG2 and the second terminal group TG2 may be functional groups connected to both ends of the second chain CC2. For example, the second self-assembled monolayer SAML2 may be represented as the following Formula 2.

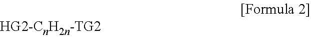

Here, n may be an integer equal to or greater than 1. HG2 represents a functional group (or reaction group) corresponding to the second head group HG2, and TG2 represents a functional group (or reaction group) corresponding to the second terminal group TG2.

The second head group HG2 may include a functional group that reacts with the second insulating layer 36. For example, the second head group HG2 may include a functional group bonded to a hydroxy group (—OH) formed on a surface of the second insulating layer 36. For example, the second head group HG2 may include a hydroxy functional group, a sulfhydryl group/thiol group (—SH), an amino functional group (—NH2), an epoxy functional group, a methoxy functional group (—OCH3), an ethoxy group (—OCH2CH3), or a silane functional group (—Si—X3). The second head group HG2 may be chemisorbed to the surface of the second insulating layer 36. In the present specification, functional groups capable of being provided as the second head group HG2 are exemplarily proposed, but the inventive concept is not limited thereto. The second head group HG2 may include a hydroxy functional group or various functional groups capable of being chemisorbed to the surface of the second insulating layer 36 as needed. In addition, in the present specification, it is described that the second self-assembled monolayer SAML2 includes the second head group HG2, but the second head group HG2 of the second self-assembled monolayer SAML2 may be provided in a form in which the second head group HG2 of the second self-assembled monolayer SAML2 is chemisorbed to the surface of the second insulating layer 36. For example, the second head group HG2 may be provided in a form in which functional groups other than the exemplarily proposed functional groups, are chemically bonded to the surface of the second insulating layer 36.

According to example embodiments, the second chain CC2 may include a hydrocarbon chain. A length of the second chain CC2, for example, a length of the hydrocarbon chain may vary as needed.

The second terminal group TG2 may include a functional group that reacts with the first terminal group TG1 of the first self-assembled monolayer SAML1. For example, the first terminal group TG1 and the second terminal group TG2 may be chemically bonded to each other. For example, the first terminal group TG1 and the second terminal group TG2 may each include a sulfhydryl group/thiol group (—SH). In the present specification, functional groups capable of being provided as the first terminal group TG1 and the second terminal group TG2 are exemplarily proposed, but the inventive concept is not limited thereto. The first terminal group TG1 and the second terminal group TG2 may include various functional groups that may be chemically bonded to each other. In addition, in the present specification, it is described that the first self-assembled monolayer SAML1 includes the first terminal group TG1, and the second self-assembled monolayer SAML2 includes the second terminal group TG2, but the first terminal group TG1 and the second terminal group TG2 may be provided in a form of being chemically bonded to each other. For example, the first terminal group TG1 and the second terminal group TG2 may be provided in a form in which functional groups other than the exemplarily proposed functional groups, are bonded to each other.

According to embodiments of the inventive concept, because the first terminal group TG1 and the second terminal group TG2 chemically bond to each other, the first self-assembled monolayer SAML1 and the second self-assembled monolayer SAML2 may form a film (for example, the first interfacial layer IFL1) connected to each other. In addition, because the first head group HG1 of the first self-assembled monolayer SAML1 is chemisorbed to the surface of the first insulating layer 16, and the second head group HG2 of the second self-assembled monolayer SAML2 is chemisorbed to the surface of the second insulating layer 36, the first interfacial layer IFL1 may firmly bond the first insulating layer 16 and the second insulating layer 36.

The second self-assembled monolayer SAML2 may include a silane coupling agent (SCA) based self-assembled monolayer. For example, the second self-assembled monolayer SAML2 may include N-(2-aminoethyl) (3-aminopropyl)methyldimethoxysilane, (3-aminopropyl)triethoxysilane, or (3-aminopropyl) trimethoxysilane with an amino functional group (—NH2). According to some embodiments, the second self-assembled monolayer SAML2 may include vinyltrimethoxysilane or vinyltriethoxysilane with a vinyl functional group (—CH═CH2). According to some embodiments, the second self-assembled monolayer SAML2 may include 3-methacryloxypropyltrimethoxysilane with a methacryloxy functional group. According to some embodiments, the second self-assembled monolayer SAML2 may have 3-glycidoxypropyltrimethoxysilane or 2-(3,4-epoxycyclohexyl)ethyltrimethoxysilane with an epoxy functional group. According to some embodiments, the second self-assembled monolayer SAML2 may include 3-mercaptopropyltrimethoxysilane with a mercapto functional group. According to some embodiments, the second self-assembled monolayer SAML2 may include 3-isocyanatopropyltrimethoxysilane with an isocyanate functional group. According to some embodiments, the second self-assembled monolayer SAML2 may include 1,3,5-tris-(trimethoxysilylpropyl) isocyanurate with an isocyanurate functional group. According to some embodiments, the second self-assembled monolayer SAML2 may include (3-chloropropyl) trimethoxysilane with a chloro functional group. However, the inventive concept is not limited thereto, and the second self-assembled monolayer SAML2 may include various self-assembled monolayers bondable to the surface of the second insulating layer 36. The second self-assembled monolayer SAML2 is described based on one molecule, but the inventive concept is not limited thereto. The second self-assembled monolayer SAML2 may include a plurality of molecules that constitute the self-assembled monolayer. In addition, the second self-assembled monolayer SAML2 may include the same material as the first self-assembled monolayer SAML1, or may include a different material from the material of the first self-assembled monolayer SAML1.

FIG. 4 is a conceptual view for describing a first interfacial layer according to an embodiment, and illustrates an example of the first interfacial layer IFL1 described with reference to FIGS. 1 to 3. FIG. 4 is only some embodiments of the inventive concept, and the inventive concept is not limited to FIG. 4.

Referring to FIG. 4, the first head group HG1 of the first self-assembled monolayer SAML1 of the first interfacial layer IFL1 may have a hydroxy functional group (—OH). The first head group HG1 may include a silane functional group (Si—(OH)₃). Any of the —OH groups of the silane functional groups of the first head group HG1 may be bonded to —OH of the surface of the first insulating layer 16. The remaining two functional groups or another functional group among the —OH groups of the silane functional groups of the first head group HG1 may be bonded to any-OH group, of the silane functional group of the first head group HG1, of another molecule adjacent thereto.

The second head group HG2 of the second self-assembled monolayer SAML2 of the first interfacial layer IFL1 may have a hydroxy functional group (—OH). The second head group HG2 may include a silane functional group (Si—(OH) 3). Any of the —OH groups of the silane functional group of the second head group HG2 may be bonded to —OH of the surface of the second insulating layer 36. The remaining two functional groups or another functional group among the —OH groups of the silane functional group of the second head group HG2 may be bonded to any-OH group, of the silane functional group of the second head group HG2, of another molecule adjacent thereto.

The first chain CC1 and the second chain CC2 may each include a hydrocarbon chain.

The first terminal group TG1 and the second terminal group TG2 may each include a sulfhydryl/thiol functional group (—SH). The first terminal group TG1 and the second terminal group TG2 may be bonded to each other. Accordingly, a S—S bond between the first self-assembled monolayer SAML1 and the second self-assembled monolayer SAML2 may be formed.

In embodiments below, for convenience of description, detailed description for technical features overlapping with those previously described with reference to FIGS. 1 to 4 will be omitted, and differences will be described in detail. The same reference numerals and symbols may be provided for the same configurations as those of the semiconductor package according to the embodiments of the inventive concept described herein.

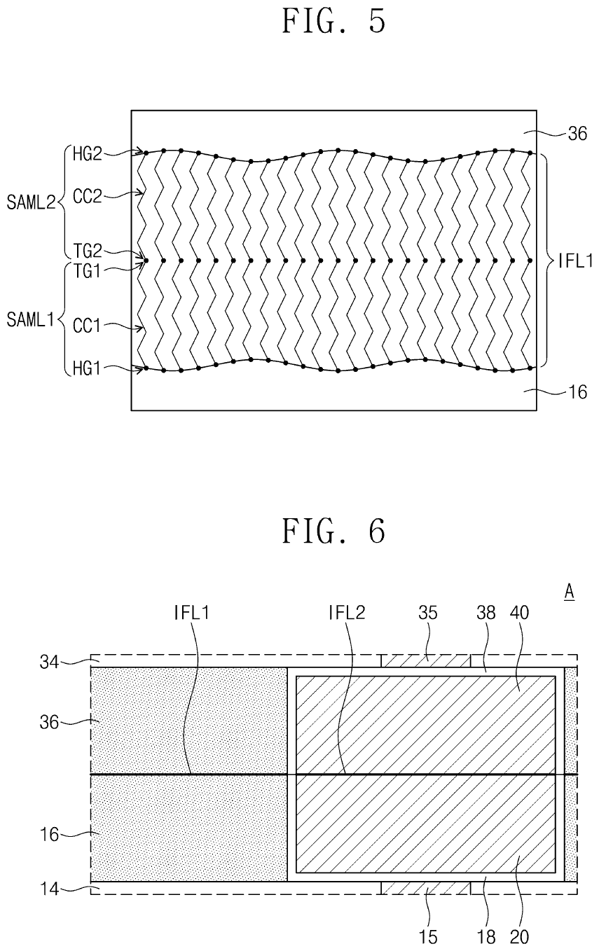

FIG. 5 is a conceptual view for exemplarily describing self-assembled monolayers in a first interfacial layer.

Referring to FIGS. 1 and 5, the surface of the first insulating layer 16 may not be flat. For example, the surface of the first insulating layer 16 may be curved as illustrated in FIG. 5. According to some embodiments, there may be a concave recess or a convex protrusion on the surface of the first insulating layer 16.

The surface of the second insulating layer 36 may not be flat. For example, the surface of the second insulating layer 36 may be curved as illustrated in FIG. 5. According to some embodiments, there may be a concave recess or a convex protrusion on the surface of the second insulating layer 36.

The first interfacial layer IFL1 may be in contact with the total upper surface of the first insulating layer 16. The first interfacial layer IFL1 may be in contact with the total lower surface of the second insulating layer 36. Because the surface of the first insulating layer 16 and the surface of the second insulating layer 36 are not flat, distances between the first insulating layer 16 and the second insulating layer 36 may be different according to positions thereof. For example, vertical thicknesses of the first interfacial layer IFL1 may be different according to planar positions thereof. The first chain CC1 of the first self-assembled monolayer SAML1 and the second chain CC2 of the second self-assembled monolayer SAML2 of the first interfacial layer IFL1 may have elasticity along a length direction. More specifically, the first self-assembled monolayer SAML1 may have a plurality of molecules that constitute a self-assembled monolayer, and the second self-assembled monolayer SAML2 may have a plurality of molecules that constitute the self-assembled monolayer. The first chains CC1 may have the same number of carbons, but may have different lengths. The second chains CC2 may have the same number of carbons, but may have different lengths. The first chain CC1 and the second chain CC2 may be expanded or contracted by an external factor. Vertical thicknesses of the first and second self-assembled monolayers SAML1 and SAML2 may be different according to planar positions thereof. Accordingly, even though the surface of the first insulating layer 16 and the surface of the second insulating layer 36 are not flat, the first chain CC1 and the second chain CC2 may not be broken, or the first and second head groups HG1 and HG2 may not be peeled from surfaces of the first and second insulating layers 16 and 36.

According to embodiments of the inventive concept, even though the surfaces of the first and second insulating layers 16 and 36 are not flat, the first interfacial layer IFL1 may be chemisorbed to the surfaces of the first and second insulating layers 16 and 36 so as not to be spaced apart from the surfaces of the first and second insulating layers 16 and 36. In addition, molecules (or chemical bonds thereof) in the first interfacial layer IFL1 may not be broken. For example, the first and second insulating layers 16 and 36 may be firmly bonded to each other through the first interfacial layer IFL1, and a semiconductor package with improved structural stability may be provided.

In addition, because the first interfacial layer IFL1 is interposed between the first and second insulating layers 16 and 36, the first and second pads 20 and 40 may not be peeled from each other due to irregularities of the surfaces of the first and second insulating layers 16 and 36. For example, the first and second pads 20 and 40 may be electrically connected to each other better, and thus the semiconductor package with improved electrical characteristics may be provided.

FIG. 6 is an enlarged diagram illustrating region A of FIG. 1.

Referring to FIGS. 1 and 6, a second interfacial layer IFL2 may be interposed between the first pads 20 and the second pads 40. The second interfacial layer IFL2 may connect the first pads 20 and the second pads 40. The second interfacial layer IFL2 may be chemically bonded to a surface of the first pads 20. The second interfacial layer IFL2 may be chemically bonded to a surface of the second pads 40. The second interfacial layer IFL2 may at least partially include a material forming the first self-assembled monolayer SAML1 and a material forming the second self-assembled monolayer SAML2. For example, molecules of the self-assembled monolayer composed of a head group (for example, the first head group HG1 or the second head group HG2), a chain (for example, the first chain CC1 or the second chain CC2), and a terminal group (for example, the first terminal group TG1 or the second terminal group TG2) may be included. The head group may be chemically bonded to the surface of the first pad 20 or the surface of the second pad 40. The second interfacial layer IFL2 may be provided so as to remove an oxide film formed on the surface of the first pad 20 or the surface of the second pad 40. This will be described in greater detail herein, together with a method for manufacturing a semiconductor package.

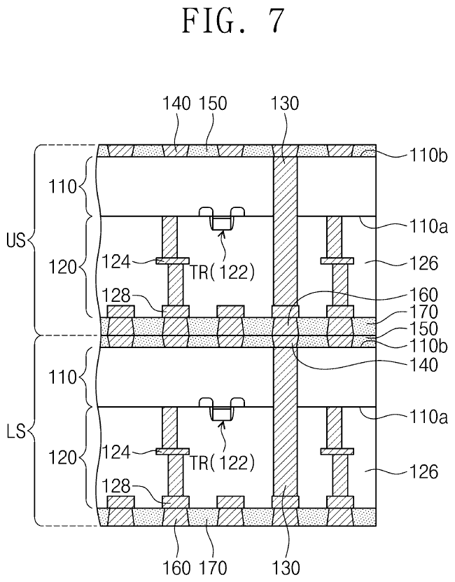

FIG. 7 is a cross-sectional view for describing a semiconductor package according to embodiments of the inventive concept.

Referring to FIG. 7, a lower structure LS and an upper structure US stacked on the lower structure LS may be provided.

The upper structure US and the lower structure LS may each include a semiconductor substrate 110, a circuit layer 120, a via 130, an upper pad 140, an upper protective film 150, a lower pad 160, and a lower protective film 170. For example, the lower structure LS and the upper structure US may each correspond to one semiconductor die. The lower structure LS and the upper structure US may respectively correspond to the lower structure 10 and the upper structure 30 described with reference to FIG. 1.

The semiconductor substrate 110 may be provided. The semiconductor substrate 110 may correspond to the first substrate 12 described with reference to FIG. 1. The semiconductor substrate 110 may have a front surface 110a and a rear surface 110b opposed to each other. Here, the front surface 110a of the semiconductor substrate 110 may be defined as one surface on which semiconductor elements are mounted in the semiconductor substrate 110, or line, pad, and the like are formed, and the rear surface 110b of the semiconductor substrate 110 may be defined as an opposite surface opposed to the front surface.

The circuit layer 120 may include a semiconductor element 122 and an element line portion 124. The circuit layer 120 may correspond to the first circuit layer 14 described with reference to FIG. 1.

The semiconductor element 122 may include at least one transistor TR provided on the front surface 110a of the semiconductor substrate 110. For example, the transistor TR may include a source and a drain formed on a lower portion of the semiconductor substrate 110, a gate electrode disposed on the front surface 110a of the semiconductor substrate 110, and a gate insulating film interposed between the semiconductor substrate 110 and the gate electrode. The semiconductor element 122 may include a memory circuit. For example, although not shown, the semiconductor element 122 may be composed of a shallow element isolation pattern, a logic cell or a plurality of memory cells, and the like on the front surface 110a of the semiconductor substrate 110. According to example embodiments, the semiconductor element 122 may include a passive element such as a capacitor.

The front surface 110a of the semiconductor substrate 110 may be covered with an element interlayer insulating film 126. The element interlayer insulating film 126 may bury the semiconductor element 122. For example, the element interlayer insulating film 126 may include at least one of silicon oxide (SiO), silicon nitride (SiN), or silicon oxynitride (SiON). According to some embodiments, the element interlayer insulating film 126 may include a low dielectric material. The element interlayer insulating film 126 may have a single-layered or multi-layered structure. When the element interlayer insulating film 126 is provided as a multi-layered structure, line layers to be described later may be provided in insulating films, and an etch stop film may be interposed between the insulating films. For example, the etch stop film may be provided on lower surfaces of the insulating films. For example, the etch stop film may include one of silicon nitride (SiN), silicon oxynitride (SiON), or silicon carbonitride (SiCN).

The element line portion 124 connected to the transistor TR may be provided in the element interlayer insulating film 126. The element line portion 124 may include line patterns for horizontally lining and connection contacts for vertically lining.

The line patterns may be placed between an upper surface and a lower surface of the element interlayer insulating film 126. FIG. 7 illustrates that one line layer is provided between the semiconductor substrate 110 and a lower surface of the element interlayer insulating film 126, for example, another portion of the line patterns is provided as one layer, but the inventive concept is not limited thereto. According to other embodiments, the other portion of the line patterns may be provided as a plurality of line layers.

The other portion (hereinafter, an under pad pattern 128) of the line patterns may be exposed to the lower surface of the element interlayer insulating film 126. For example, the under pad pattern 128 may be a line pattern provided at the lowermost end of the element line portion 124 provided in the element interlayer insulating film 126. The under pad pattern 128 may be partially connected to the semiconductor element 122.

The connection contacts may connect the line patterns each other, or may connect the line patterns and the semiconductor element 122 or the semiconductor substrate 110. For example, portions of the connection contacts may vertically penetrate the element interlayer insulating film 126 to be connected to any one of the source electrode, the drain electrode, or the gate electrode of the transistor TR, or to be connected to various elements of the semiconductor element 122. For example, the element line portion 124 may include or may be tungsten (W).

The vias 130 may vertically penetrate the semiconductor substrate 110 and the element interlayer insulating film 126 to be partially connected to an upper surface of the under pad pattern 128. The vias 130 may vertically penetrate the element interlayer insulating film 126 and the semiconductor substrate 110 to be exposed onto an upper surface of the semiconductor substrate 110. For example, the vias 130 may include or may be tungsten (W).

The lower pads 160 may be disposed on the element interlayer insulating film 126. The lower pads 160 may be disposed on a lower surface of the under pad pattern 128. The lower pads 160 may include or may be a metal material. For example, the lower pads 160 may include or may be copper (Cu).

The lower protective film 170 may be disposed on the element interlayer insulating film 126. The lower protective film 170 may cover the element line portion 124 on a lower surface of the element interlayer insulating film 126. A lower surface of the lower protective film 170 may be substantially flat. The lower protective film 170 may surround the lower pads 160 on the lower surface of the element interlayer insulating film 126. The lower pads 160 may be exposed by the lower protective film 170. The lower surface of the lower protective film 170 may be substantially coplanar with the lower surfaces of the lower pads 160. The lower protective film 170 may include or may be one of silicon nitride (SiN), silicon oxide (SiO), silicon oxycarbide (SiOC), silicon oxynitride (SiON), or silicon carbonitride (SiCN).

The upper pads 140 may be disposed on the rear surface 110b of the semiconductor substrate 110. The upper pads 140 may be partially connected to the vias 130. For example, the vias 130 may vertically penetrate the semiconductor substrate 110 to be connected to lower surfaces of the upper pads 140. The upper pads 140 may include or may be a metal material. For example, the upper pads 140 may include or may be copper (Cu).

The upper protective film 150 may be disposed on the rear surface 110b of the semiconductor substrate 110. An upper surface of the upper protective film 150 may be substantially flat. The upper protective film 150 may surround the upper pads 140 on the semiconductor substrate 110. The upper pads 140 may be exposed by the upper protective film 150. The upper surface of the upper protective film 150 may be substantially coplanar with the upper surfaces of the upper pads 140. The upper protective film 150 may include or may be one of silicon nitride (SiN), silicon oxide (SiO), silicon oxycarbide (SiOC), silicon oxynitride (SiON), or silicon carbonitride (SiCN).

The upper structure US may substantially have the same structure as, or a similar structure to, the lower structure LS. For example, the upper structure US may include the semiconductor substrate 110, the circuit layer 120, the via 130, the upper pad 140, the upper protective film 150, the lower pad 160, and the lower protective film 170. For example, the upper structure US may correspond to one semiconductor die. The upper structure US may correspond to the upper structure 30 described with reference to FIG. 1.

The upper structure US may be disposed on the lower structure LS. The upper pads 140 of the lower structure LS and the lower pads 160 of the upper structure US may be vertically aligned with respect to each other. The lower structure LS and the upper structure US may be in contact with each other.

At an interface of the lower structure LS and the upper structure US, the upper protective film 150 of the lower structure LS and the lower protective film 170 of the upper structure US may be bonded to each other. As described with reference to FIGS. 1 to 6, an interfacial layer may be provided between the upper protective film 150 of the lower structure LS and the lower protective film 170 of the upper structure US. The interfacial layer may have a first self-assembled monolayer chemisorbed onto the upper surface of the upper protective film 150 of the lower structure LS and a second self-assembled monolayer chemisorbed onto the lower surface of the lower protective film 170 of the upper structure US. A terminal group of the first self-assembled monolayer and a terminal group of the second self-assembled monolayer may be chemically bonded to each other. Accordingly, the upper protective film 150 of the lower structure LS and the lower protective film 170 of the upper structure US may be firmly bonded to each other using the interfacial layer.

The upper structure US may be connected to the lower structure LS. Specifically, the upper structure US may be in contact with the lower structure LS. At the interface of the upper structure US and the lower structure LS, the upper pads 140 of the lower structure LS and the lower pads 160 of the upper structure US may be bonded to each other. In this case, the upper pads 140 of the lower structure LS and the lower pads 160 of the upper structure US may form an intermetallic hybrid bonding. For example, the upper pads 140 of the lower structure LS and the lower pads 160 of the upper structure US bonded to each other may have a continuous configuration, and a boundary surface between the upper pads 140 of the lower structure LS and the lower pads 160 of the upper structure US may not be visualized. For example, the upper pads 140 of the lower structure LS and the lower pads 160 of the upper structure US may be composed of the same material so that there may be no interface therebetween. For example, the upper pads 140 of the lower structure LS and the lower pads 160 of the upper structure US may be bonded to each other, such that they are integrally formed.

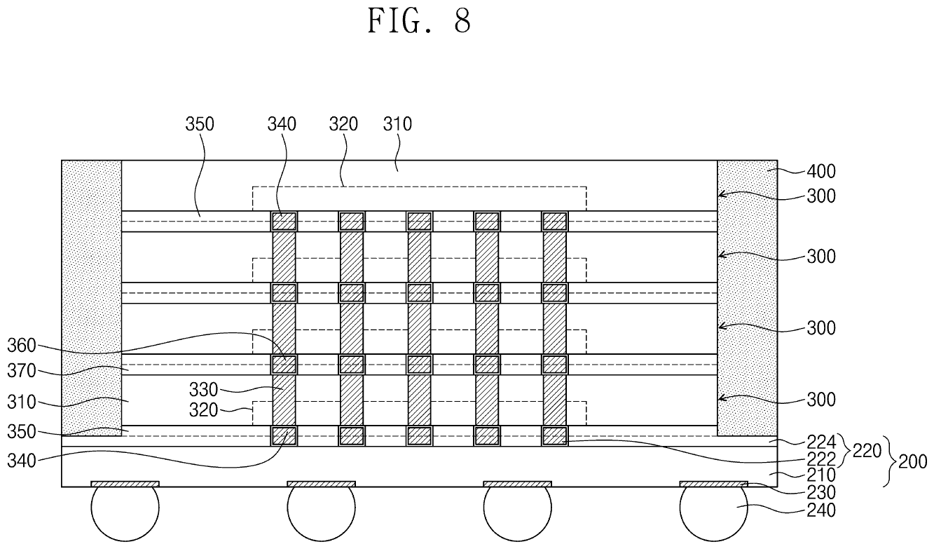

FIG. 8 is a cross-sectional view for describing a semiconductor module according to embodiments of the inventive concept.

Referring to FIG. 8, a substrate 200 may be provided. The substrate 200 may be a substrate for packaging such as a printed circuit board PCB, or an interposer substrate provided in a package. According to some embodiments, the substrate 200 may be a semiconductor substrate on which semiconductor devices are formed or integrated. The semiconductor device may be a semiconductor chip (i.e., a semiconductor device singulated from (e.g., cut from) a wafer). The substrate 200 may include a substrate base layer 210, and a substrate line layer 220 formed on the substrate base layer 210. The substrate line layer 220 may include first substrate pads 222 exposed onto an upper surface of the substrate base layer 210, and a substrate protective film 224 covering the substrate base layer 210 and surrounding the first substrate pads 222. According to example embodiments, upper surfaces of the first substrate pads 222 may be coplanar with an upper surface of the substrate protective film 224. Second substrate pads 230 exposed onto a lower surface of the substrate base layer 210 may be provided. The first substrate pads 222 and the second substrate pads 230 may include or may be a conductive material such as metal. For example, the first substrate pads 222 and the second substrate pads 230 may include or may be copper (Cu). The substrate protective film 224 may include or may be an insulating material such as an oxide, a nitride, or an oxynitride of a material forming the substrate base layer 210. For example, the substrate protective film 224 may include or may be silicon oxide (SiO).

Substrate connection terminals 240 may be disposed on a lower surface of the substrate 200. The substrate connection terminals 240 may be provided on the second substrate pads 230 of the substrate 200. The substrate connection terminals 240 may each include a solder ball, a solder bump, or the like. The semiconductor module may be provided in a form of a ball grid array (BGA), a fine ball grid array (FBGA), or a land grid array (LGA) according to types and disposition of the substrate connection terminals 240.

A chip stack may be disposed on the substrate 200. The chip stack may include at least one semiconductor chip 300 stacked on the substrate 200. Each of the semiconductor chips 300 may be a memory chip such as DRAM, SRAM, MRAM, or flash memory. According to some embodiments, each of the semiconductor chips 300 may be a logic chip. FIG. 8 illustrates that one chip stack is disposed, but the inventive concept is not limited thereto. When the chip stack is provided in plurality, the chip stacks may be spaced apart from each other on the substrate 200.

Each of the semiconductor chips 300 may include a semiconductor substrate 310, a circuit layer 320, a via 330, a lower chip pad 340, a lower protective film 350, an upper chip pad 360, and an upper protective film 370. For example, the semiconductor chips 300 may each correspond to one semiconductor die. An uppermost semiconductor chip 300 may not include the via 330, the upper chip pad 360, and the upper protective film 370.

Each of the semiconductor chips 300 may have the same structure as or a similar structure to the lower structure LS or the upper structure US described with reference to FIG. 7. Description for the lower structure LS or the upper structure US of FIG. 7 may be applied to the semiconductor chips 300 in the same manner.

A molding film 400 may cover the chip stack on the substrate 200. The molding film 400 may protect the chip stack. The molding film 400 may include an insulating material. For example, the molding film 400 may include an epoxy molding compound (EMC).

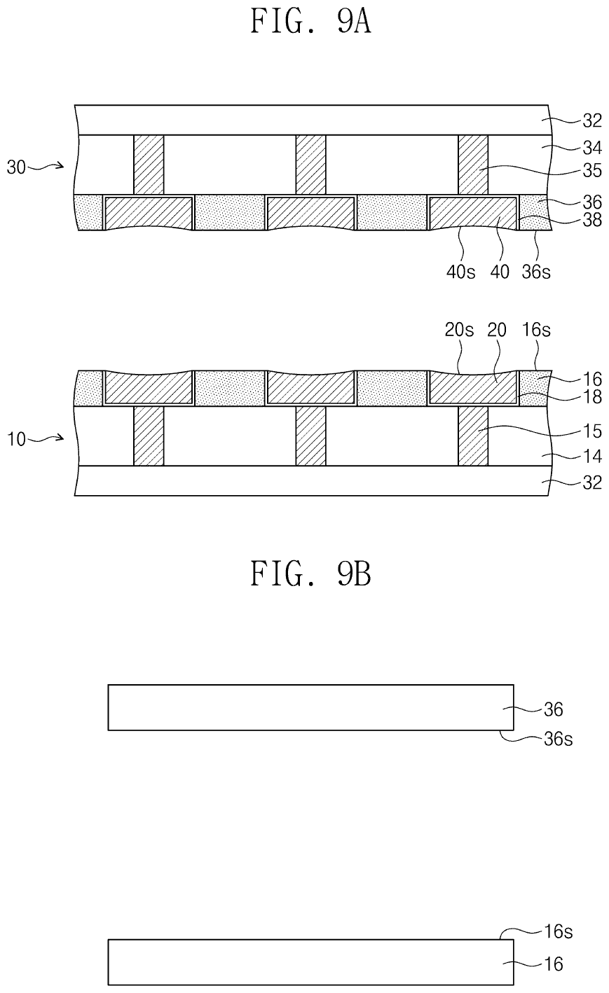

FIGS. 9A to 12A are cross-sectional views for describing a method for manufacturing a semiconductor package according to embodiments of the inventive concept. FIGS. 9B to 12B are conceptual views for describing some embodiments of a first interfacial layer in the method for manufacturing a semiconductor package according to embodiments of the inventive concept, and illustrate an example in which first and second self-assembled monolayers of the first interfacial layer have a head group of a silane functional group (—Si—OH3) and a terminal group of a sulfhydryl/thiol group (—SH) like FIG. 4. FIGS. 9B to 12B are only some embodiments of the inventive concept, and the inventive concept is not limited by FIGS. 9B to 12B.

Referring to FIGS. 9A and 9B, a first substrate 12 may be provided. The first substrate 12 may be a semiconductor substrate.

A first circuit layer 14 may be formed on the first substrate 12. The first circuit layer 14 may have a first connection line 15 for connecting the first substrate 12 and the first pads 20.

A first insulating layer 16 may be formed by depositing an insulating material on the first circuit layer 14. The first insulating layer 16 may cover the first circuit layer 14.

Openings for providing the first pads 20 may be formed by patterning the first insulating layer 16. For example, a portion of the opening may expose the first connection line 15. According to some embodiments, the other portion of the opening may expose an upper surface of the first circuit layer 14.

First seed/barrier patterns 18 and the first pads 20 may be formed on the first insulating layer 16. For example, a seed/barrier film may be formed on the first insulating layer 16. The seed/barrier film may be formed so as to conformally cover the first insulating layer 16. For example, the seed/barrier film may cover an upper surface 16s of the first insulating layer 16, and inner side surfaces and bottom surfaces of the openings. A conductive layer that fills the openings may be formed on the first insulating layer 16. A process of forming the conductive layer may include a plating process using the seed/barrier film as a seed. A planarization process may be performed on the conductive layer. The planarization process may include a chemical mechanical polishing (CMP) process. The first pads 20 and the first seed/barrier patterns 18 may be formed in the openings by the planarization process. For example, the conductive layer and the seed/barrier film on the upper surface 16s of the first insulating layer 16 may be partially removed, and the upper surface 16s of the first insulating layer 16 may be exposed. The conductive layer may be overetched during the planarization process. For example, the first pads 20 may be partially overetched so that an upper surface 20s thereof may become concave. The lower structure 10 may be formed in the above manner.

An upper structure 30 may be formed. A process of forming the upper structure 30 may be substantially the same as, or similar to, a process of forming the lower structure 10. For example, a second substrate 32 may be provided. A second circuit layer 34 may be formed on the second substrate 32. A second insulating layer 36 may be formed on the second circuit layer 34. A seed/barrier film and a conductive layer may be formed by patterning the second insulating layer 36, and then filling the openings of the second insulating layer 36 with a conductive material. Second pads 40 may be formed by performing a planarization process on the conductive layer and the seed/barrier film. The conductive layer may be overetched during the planarization process. For example, the second pads 40 may be partially overetched so that a lower surface 40s thereof may become concave. The upper structure 30 may be formed in the above manner.

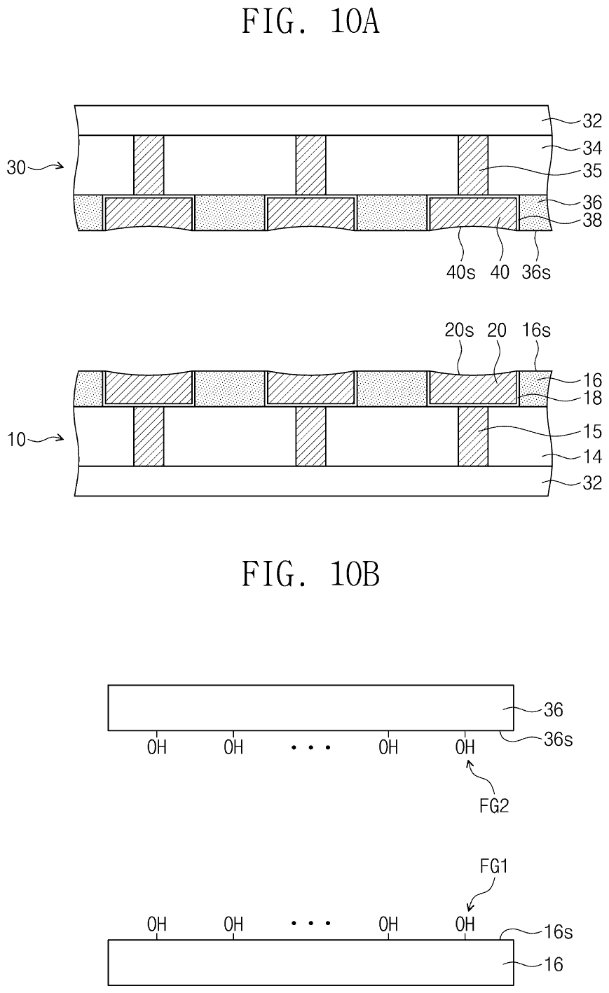

Referring to FIGS. 10A and 10B, a first surface treatment process may be performed on the upper surface 16s of the first insulating layer 16 of the lower structure 10. First functional groups FG1 may be formed on the upper surface 16s of the first insulating layer 16 by the first surface treatment process. For example, as illustrated in FIG. 10B, the first functional groups FG1 formed on the upper surface 16s of the first insulating layer 16 may be hydroxy functional groups (—OH).

A second surface treatment process may be performed on a lower surface 36s of the second insulating layer 36 of the upper structure 30. Second functional groups FG2 may be formed on the lower surface 36s of the second insulating layer 36 by the second surface treatment process. For example, as illustrated in FIG. 10B, the second functional groups FG2 formed on the lower surface 36s of the second insulating layer 36 may be hydroxy functional groups (—OH).

The first surface treatment process and the second surface treatment process may include a surface treatment process using plasma, a cleaning process using DI water, and the like. However, the inventive concept is not limited thereto, and the first and second surface treatment processes may include various processes for modifying surfaces of the first insulating layer 16 and the second insulating layer 36.

The first and second surface treatment processes may be separately performed as separate processes, or may be simultaneously performed in one chamber.

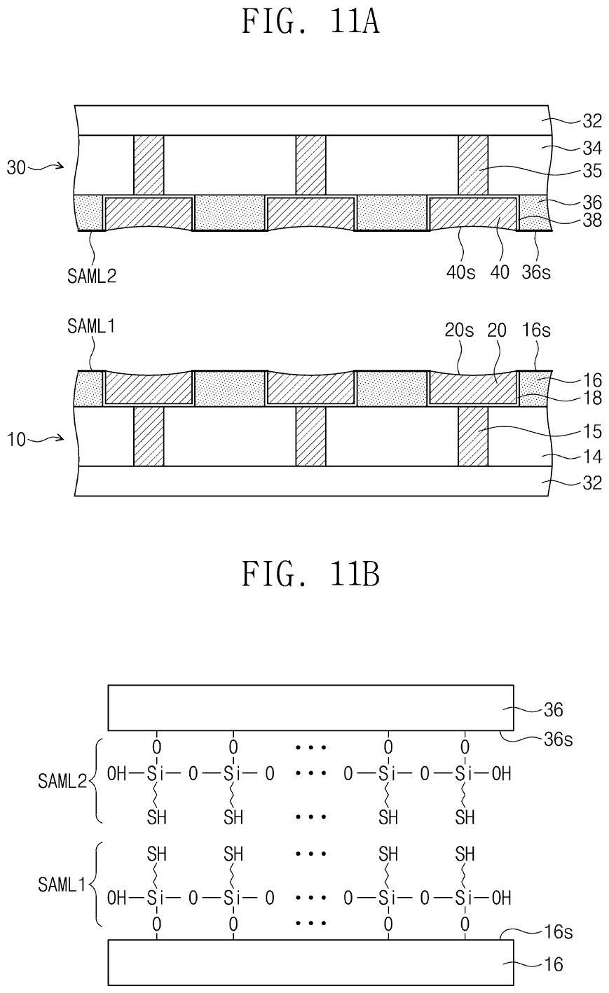

Referring to FIGS. 11A and 11B, a first self-assembled monolayer SAML1 may be formed on the first insulating layer 16. The first self-assembled monolayer SAML1 may correspond to the first self-assembled monolayer SAML1 described with reference to FIGS. 1 to 5. For example, the first self-assembled monolayer SAML1 may include a first head group HG1, a first terminal group TG1, and a first chain CC1 connecting the first head group HG1 and the first terminal group TG1. The first head group HG1 and the first terminal group TG1 may be functional groups connected to both ends of the first chain CC1. The first head group HG1 may be chemically bonded to the first functional group FG1 formed on the upper surface 16s of the first insulating layer 16. For example, as illustrated in FIG. 11B, when the first head group HG1 includes a silane functional group (—Si—OH3), the first functional group FG1 and one of —OH groups of the first head group HG1 may be bonded to each other to form a covalent bond (—O—) with an oxygen therebetween. Another one of the —OH groups of the first head group HG1 may be bonded to an —OH group of the first head group HG1 of another adjacent molecule to align molecules of the first self-assembled monolayer SAML1.

A second self-assembled monolayer SAML2 may be formed on the second insulating layer 36. The second self-assembled monolayer SAML2 may correspond to the second self-assembled monolayer SAML2 described with reference to FIGS. 1 to 5. For example, the second self-assembled monolayer SAML2 may include a second head group HG2, a second terminal group TG2, and a second chain CC2 connecting the second head group HG2 and the second terminal group TG2. The second head group HG2 and the second terminal group TG2 may be functional groups connected to both ends of the second chain CC2. The second head group HG2 may be chemically bonded to the second functional group FG2 formed on the lower surface 36s of the second insulating layer 36. For example, as illustrated in FIG. 11B, when the second head group HG2 includes a silane functional group (—Si—OH3), the second functional group FG2 and one of —OH groups of the second head group HG2 may be bonded to each other to form a covalent bond (—O—) with an oxygen therebetween. Another one of the —OH groups of the second head group HG2 may be bonded to an —OH group of the second head group HG2 of another adjacent molecule to align molecules of the second self-assembled monolayer SAML2.

According to example methods, a first self-assembled monolayer and a second self-assembled monolayer for a first interfacial layer may be prepared sequentially (with either being prepared before the other), or concurrently or partially concurrently. Similarly, a first self-assembled monolayer and a second self-assembled monolayer for a second (or third or fourth, etc.) interfacial layer may be prepared sequentially (with either being prepared before the other), or concurrently or partially concurrently. Additionally, the first interfacial layer and the second (or third or fourth, etc.) interfacial layer may be prepared sequentially or concurrently.

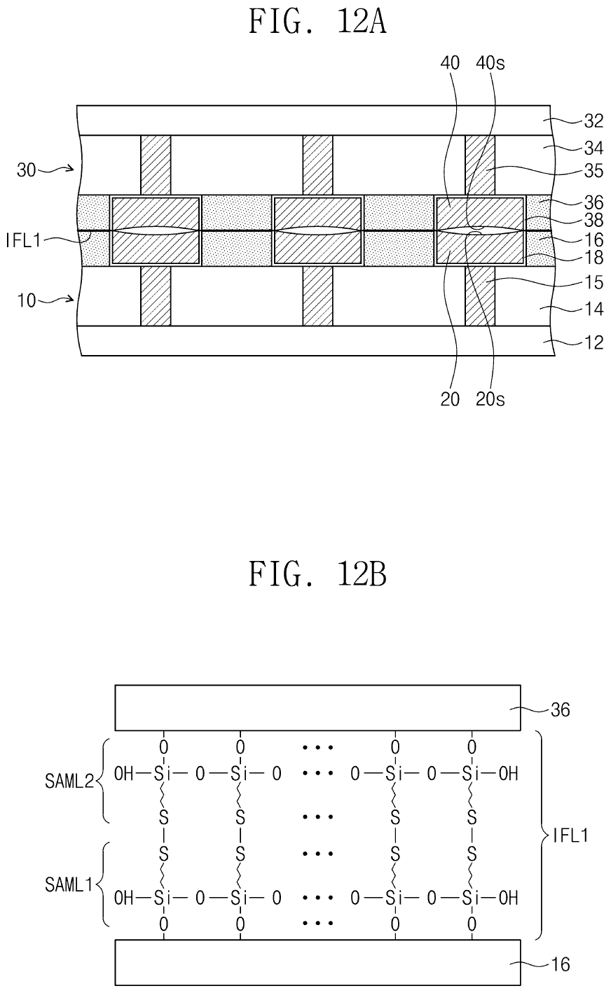

Referring to FIGS. 12A and 12B, the first self-assembled monolayer SAML1 and the second self-assembled monolayer SAML2 may be bonded to each other to form a first interfacial layer IFL1. For example, the first terminal group TG1 of the first self-assembled monolayer SAML1 and the second terminal group TG2 of the second self-assembled monolayer SAML2 may be chemically bonded to each other. For example, as illustrated in FIG. 11B, when the first terminal group TG1 and the second terminal group TG2 include a sulfhydryl/thiol group (—SH), the —SH group of the first terminal group TG1 and the —SH group of the second terminal group TG2 may be bonded to each other to form a covalent bond (for example, a disulfide bond (S—S)).

According to embodiments of the inventive concept, the first and second insulating layers 16 and 36 may be bonded to each other as a strong covalent bond, and the first and second self-assembled monolayers SAML1 and SAML2 may be bonded as a strong covalent bond. Accordingly, a bond between the first and second insulating layers 16 and 36 may be strong, and a semiconductor package with improved structural stability may be manufactured. In addition, the first and second self-assembled monolayers SAML1 and SAML2 may be respectively directly formed on the surfaces 16s and 36s of the first and second insulating layers 16 and 36, and thus the first and second self-assembled monolayers SAML1 and SAML2 may not be spaced apart from the first and second insulating layers 16 and 36. The first and second self-assembled monolayers SAML1 and SAML2 may be in contact with each other to be easily chemically bonded to each other due to the first and second chains CC1 and CC2 expandable or contractable. Accordingly, the first interfacial layer IFL1 may be formed on the surfaces 16s and 36s of the first and second insulating layers 16 and 36 without spacing therebetween, and a defect caused by the spacing may be reduced.

Referring continuously to FIG. 1, an annealing process may be performed on the first and second pads 20 and 40. Volumes of the first and second pads 20 and 40 may be expanded by the annealing process. Upper surfaces 20s of the first pads 20 may become higher. Lower surfaces 40s of the second pads 40 may become lower. Because the volumes of the first and second pads 20 and 40 continuously expand, the upper surfaces 20s of the first pads 20 and the lower surfaces 40s of the second pads 40 may be in contact with each other. After the upper surfaces 20s of the first pads 20 and the lower surfaces 40s of the second pads 40 are in contact with each other, the first pads 20 and the second pads 40 may be bonded to each other by the annealing process. The first pads 20 and the second pads 40 may be naturally bonded to each other. Specifically, the first pads 20 and the second pads 40 may be formed of the same material (for example, copper (Cu), or the like), and may be bonded by an intermetallic hybrid bonding process caused by surface activation on boundary surfaces of the first pads 20 and the second pads 40 in contact with each other.

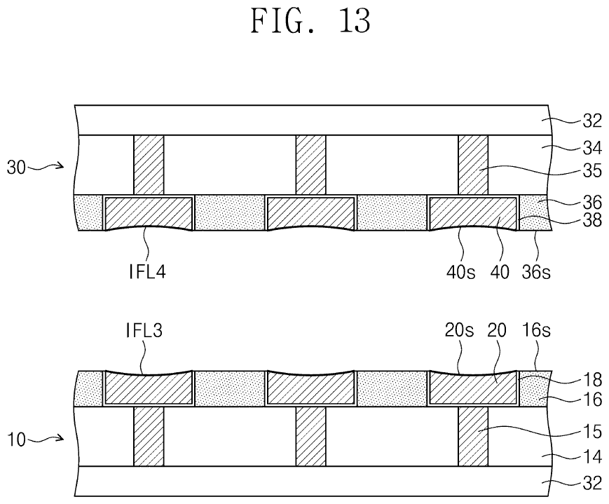

FIGS. 13 to 15 are cross-sectional views for describing a method for manufacturing a semiconductor package according to embodiments of the inventive concept.

As described with reference to FIGS. 9A and 9B, a lower structure 10 and an upper structure 30 may be formed.

Referring to FIG. 13, a first surface treatment process may be performed on an upper surface 16s of a first insulating layer 16 of a lower structure 10. The first surface treatment process may be substantially the same as, or similar to, what is described with reference to FIGS. 10A and 10B. For example, first functional groups FG1 may be formed on the upper surface 16s of the first insulating layer 16 by the first surface treatment process. Third interfacial layers IFL3 may be formed on an upper surface 20s of first pads 20 during the first surface treatment process. The third interfacial layers IFL3 may be formed on the upper surface 20s of the first pads 20 during the first surface treatment process. For example, the third interfacial layers IFL3 may be metal oxide films formed by oxidizing the first pads 20.

A second surface treatment process may be performed on a lower surface 36s of a second insulating layer 36 of the upper structure 30. The second surface treatment process may be substantially the same as, or similar to, what is described with reference to FIGS. 10A and 10B. For example, second functional groups FG2 may be formed on the lower surface 36s of the second insulating layer 36 by the second surface treatment process. Fourth interfacial layers IFL4 may be formed on the lower surface 40s of the second pads 40 during the second surface treatment process. The fourth interfacial layers IFLA may be formed on the lower surface 40s of the second pads 40 during the second surface treatment process. For example, the fourth interfacial layers IFL4 may be metal oxide films formed by oxidizing the second pads 40.

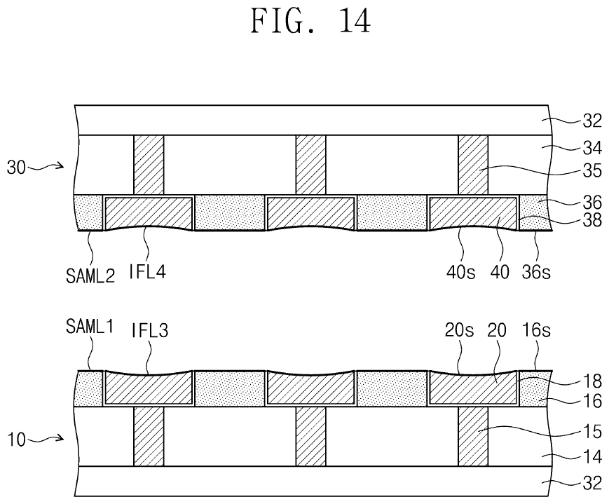

Referring to FIG. 14, a first self-assembled monolayer SAML1 may be formed on the first insulating layer 16. A process of forming the first self-assembled monolayer SAML1 may be substantially the same as, or similar to, what is described with reference to FIGS. 11A and 11B. For example, the first head group HG1 of the first self-assembled monolayer SAML1 may be chemically bonded to the first functional group FG1 formed on the upper surface 16s of the first insulating layer 16. In this case, a first source material for forming the first self-assembled monolayer SAML1 may partially chemically react with the third interfacial layer IFL3. For example, one of functional groups (a first head group or a first terminal group) of the first source material may react with the third interfacial layer IFL3. A metal oxide film forming the third interfacial layer IFL3 may be removed through the reaction. For example, when the first terminal group includes a sulfhydryl/thiol group (—SH), a hydrogen atom of the sulfhydryl/thiol group of the first terminal group and an oxygen atom of the third interfacial layer IFL3 may be bonded to each other to form water. The water may be removed from the upper surface 20s of the first pads 20. In this case, the first source material may be bonded to the upper surface 20s of the first pads 20. For example, the third interfacial layer IFL3 may be substituted to an interfacial layer including the first source material for forming the first self-assembled monolayer SAML1 in the metal oxide film. Unlike what is illustrated in FIG. 14, the first source material may be removed from the upper surface 20s of the first pads 20. For example, another oxide film or interfacial layer may not be present on the upper surface 20s of the first pads 20. The first source material for forming the first self-assembled monolayer SAML1 may have a first chain composed of a hydrocarbon chain. The first source material may have a higher conductivity than the metal oxide film.

A second self-assembled monolayer SAML2 may be formed on the second insulating layer 36. A process of forming the second self-assembled monolayer SAML2 may be substantially the same as, or similar to, what is described with reference to FIGS. 11A and 11B. For example, the second head group HG2 of the second self-assembled monolayer SAML2 may be chemically bonded to the second functional groups FG2 formed on the lower surface 36s of the second insulating layer 36. In this case, a second source material for forming the second self-assembled monolayer SAML2 may partially chemically react with the fourth interfacial layers IFLA. For example, one of functional groups (a second head group or a second terminal group) of the second source material may react with the fourth interfacial layers IFL4. A metal oxide film forming the fourth interfacial layers IFLA may be removed through the reaction. For example, when the second terminal group includes a sulfhydryl/thiol group (—SH), a hydrogen atom of the sulfhydryl/thiol group of the second terminal group and an oxygen atom of the fourth interfacial layers IFLA may be bonded to each other to form water. The water may be removed from the lower surface 40s of the second pads 40. In this case, the second source material may be bonded to the lower surface 40s of the second pads 40. For example, the fourth interfacial layers IFL4 may be substituted to an interfacial layer including the source material for forming the second self-assembled monolayer SAML2 in the metal oxide film. Unlike what is illustrated in FIG. 14, the second source material may be removed from the lower surface 40s of the second pads 40. For example, another oxide film or interfacial layer may not be present on the lower surface 40s of the second pads 40. The second source material for forming the second self-assembled monolayer SAML2 may have a second chain composed of a hydrocarbon chain. Accordingly, the second source material may have a higher conductivity than the metal oxide film.

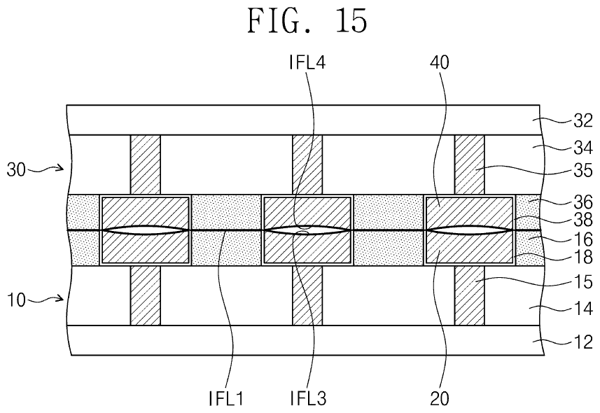

Referring to FIG. 15, the first self-assembled monolayer SAML1 and the second self-assembled monolayer SAML2 may be bonded to each other to form the first interfacial layer IFL1. Bonding the first self-assembled monolayer SAML1 and the second self-assembled monolayer SAML2 may be substantially the same as, or similar to, what is described with reference to FIGS. 12A and 12B. For example, the first terminal group TG1 of the first self-assembled monolayer SAML1 and the second terminal group TG2 of the second self-assembled monolayer SAML2 may be chemically bonded to each other.

Referring back to FIG. 6, an annealing process may be performed on the first and second pads 20 and 40. Volumes of the first and second pads 20 and 40 may be expanded by the annealing process. The upper surfaces 20s of the first pads 20 may become higher. The lower surfaces 40s of the second pads 40 may become lower. Because the volumes of the first and second pads 20 and 40 continuously expand, the third interfacial layer IFL3 and the fourth interfacial layer IFL4 may be in contact with each other. The third interfacial layer IFL3 and the fourth interfacial layer IFL4 may be in contact with each other to form the second interfacial layers IFL2.

According to embodiments of the inventive concept, oxide films of the surfaces of the first and second pads 20 and 40 generated in a process of forming and bonding the lower structure 10 and the upper structure 30 may be removed. Accordingly, after hybrid bonding of the first and second pads 20 and 40, the first and second pads 20 and 40 may be integrally formed without any foreign matter such as an oxide layer there inside, and electrical resistance between the first and second pads 20 and 40 may be low. When the second interfacial layer IFL2 is formed between the first and second pads 20 and 40, the second interfacial layers IFL2 may have lower electrical resistances than the oxide films. For example, a semiconductor package with improved electrical characteristics may be provided.

In addition, a process of removing the oxide films on the surfaces of the first and second pads 20 and 40 may be simultaneously performed with a process of forming the first and second self-assembled monolayers SAML1 and SAML2 on the surfaces of the first and second insulating layers 16 and 36. For example, the method for manufacturing a semiconductor package with a simplified process may be provided.

In a semiconductor package according to embodiments of the inventive concept, insulating layers and self-assembled monolayers may be bonded by a strong covalent bond, and the self-assembled monolayers may be also bonded by a strong covalent bond. Accordingly, the insulating layers may be strongly bonded to each other, and the semiconductor package with improved structural stability may be manufactured. In addition, because the self-assembled monolayers are directly formed on surfaces of the insulating layers, the self-assembled monolayers may not be spaced apart from the insulating layers. Due to chains expandable or contractable, the self-assembled monolayers may be in contact with each other to be chemically easily bonded to each other. Accordingly, a first interfacial layer may be formed on the surfaces of the insulating layers without spacing therebetween. For example, there may be fewer defects caused by the spacing, and the semiconductor package with improved structural stability may be provided.

In addition, even though the surfaces of the insulating layers are not flat, the first interfacial layer may be chemisorbed to the surfaces of the insulating layers without spacing. Molecules (or chemical bonds) in the first interfacial layer may not be broken. For example, the insulating layers may be firmly bonded to each other through the first interfacial layer, and the semiconductor package with improved structural stability may be provided.

According to embodiments of the inventive concept, oxide films on surfaces of pads generated in a process of forming and bonding a lower structure and an upper structure may be removed. Accordingly, after hybrid bonding of the pads, the pads may be integrally formed without any foreign matter, such as an oxide layer therebetween, and electrical resistances between the pads may be low. When second interfacial layers are formed between the pads, the second interfacial layers may have lower electrical resistances than the oxide films. For example, the semiconductor package with improved electrical characteristics may be provided.

Although the embodiments of the present invention have been described, it is understood that the present invention should not be limited to these embodiments, but various changes and modifications can be made by one ordinary skilled in the art within the spirit and scope of the present invention as hereinafter claimed.

What is claimed is:

1. A semiconductor package comprising:
a lower structure;
an upper structure on the lower structure; and
a first interfacial layer between the lower structure and the upper structure,
wherein the lower structure includes:
a first semiconductor substrate;
a first pad on the first semiconductor substrate; and
a first insulating layer surrounding the first pad on the first semiconductor substrate,
wherein the upper structure includes:
a second semiconductor substrate;
a second pad on the second semiconductor substrate; and
a second insulating layer surrounding the second pad on the second semiconductor substrate, and
wherein the first interfacial layer includes:
a first self-assembled monolayer bonded to the first insulating layer; and
a second self-assembled monolayer bonded to the second insulating layer.

2. The semiconductor package of claim 1,
wherein the first self-assembled monolayer comprises:
a first chain;
a first head group connected to a first end of the first chain; and
a first terminal group connected to an opposite second end of the first chain,
wherein the first self-assembled monolayer is chemisorbed to a first surface of the first insulating layer by the first head group, and
wherein the second self-assembled monolayer comprises:
a second chain;
a second head group connected to a first end of the second chain; and
a second terminal group connected to an opposite second end of the second chain,
wherein the second self-assembled monolayer is chemisorbed to a second surface of the second insulating layer by the second head group, and
wherein the first terminal group and the second terminal group are bonded to each other.

3. The semiconductor package of claim 2, wherein the first head group and the second head group each comprise a functional group bondable to a hydroxy group (—OH).

4. The semiconductor package of claim 2, wherein the first chain and the second chain each comprise a hydrocarbon chain.

5. The semiconductor package of claim 1, wherein the first self-assembled monolayer and the second self-assembled monolayer each comprise a silane coupling agent (SCA).

6. The semiconductor package of claim 1, wherein a first surface of the first insulating layer bonded to the first self-assembled monolayer is curved, and
a second surface of the second insulating layer bonded to the second self-assembled monolayer is curved.

7. The semiconductor package of claim 1, wherein the first interfacial layer is in contact with the first insulating layer and the second insulating layer, and is spaced apart from the first pad and the second pad.

8. The semiconductor package of claim 7, wherein
the first self-assembled monolayer is in contact with a first total area of a first surface of the first insulating layer,
the second self-assembled monolayer is in contact with a second total area of a second surface of the second insulating layer,
vertical thicknesses of the first self-assembled monolayer are different from each other according to planar positions thereof, and
vertical thicknesses of the second self-assembled monolayer are different from each other according to planar positions thereof.

9. The semiconductor package of claim 1, wherein the first pad and the second pad are in contact with each other, integrally connecting the first pad and the second pad to one another.

10. The semiconductor package of claim 1, further comprising a second interfacial layer between the first pad and the second pad,
wherein the second interfacial layer includes a first material forming a first self-assembled monolayer of the second interfacial layer and a second material forming a second self-assembled monolayer of the second interfacial layer.

11. The semiconductor package of claim 1, wherein each of the first insulating layer and the second insulating layer comprises silicon oxide (SiO) or silicon carbonitride (SiCN).

12. The semiconductor package of claim 1, wherein the first self-assembled monolayer comprises a different material from a material of the second self-assembled monolayer.

13. A semiconductor package comprising:
a first semiconductor substrate;
a second semiconductor substrate on the first semiconductor substrate;
a first insulating layer on a first surface of the first semiconductor substrate facing the second semiconductor substrate;
a second insulating layer on a second surface of the second semiconductor substrate facing the first semiconductor substrate; and
a first interfacial layer between the first insulating layer and the second insulating layer,
wherein the first interfacial layer includes:
a first head group of a first self-assembled monolayer, the first head group being chemisorbed to a first surface of the first insulating layer, bonding the first surface of the first insulating layer to the first self-assembled monolayer;
a second head group of a second self-assembled monolayer, the second head group being chemisorbed to a second surface of the second insulating layer, bonding the second surface of the second insulating layer to the second self-assembled monolayer;
wherein the first self-assembled monolayer includes a first hydrocarbon chain connecting the first head group and a first terminal group;
wherein the second self-assembled monolayer includes a second hydrocarbon chain connecting the second head group and a second terminal group; and
wherein the first terminal group and the second terminal group are chemically bonded to each other between the first head group and the second head group.

14. The semiconductor package of claim 13, wherein the first head group and the second head group each comprise a functional group bondable to a hydroxy group (—OH).

15. The semiconductor package of claim 13,
wherein the first surface of the first insulating layer bonded to the first self-assembled monolayer, is curved, and
the second surface of the second insulating layer bonded to the second self-assembled monolayer, is curved.

16. The semiconductor package of claim 13, wherein the first insulating layer comprises silicon oxide (SiO) or silicon carbonitride (SiCN); and the second insulating layer comprises silicon oxide (SiO) or silicon carbonitride (SiCN).

17. The semiconductor package of claim 13, further comprising:
a first pad on the first surface of the first semiconductor substrate, and planarly surrounded by the first insulating layer; and
a second pad on the second surface of the second semiconductor substrate, and planarly surrounded by the second insulating layer,
wherein the first pad and the second pad are in contact with each other, and the first interfacial layer surrounds the first pad and the second pad in a plan view.

18. A method for manufacturing a semiconductor package, the method comprising:
forming, on a first semiconductor substrate, a first pad, and a first insulating layer surrounding the first pad;
performing a first surface treatment process on a first surface of the first insulating layer, the first surface treatment process forming a first functional group on the first surface;
forming a first self-assembled monolayer on the first surface of the first insulating layer, the first self-assembled monolayer having a first head group bonded to the first functional group;
forming, on a second semiconductor substrate, a second pad, and a second insulating layer surrounding the second pad;
performing a second surface treatment process on a second surface of the second insulating layer, the second surface treatment process forming a second functional group on the second surface;
forming a second self-assembled monolayer on the second surface of the second insulating layer, the second self-assembled monolayer having a second head group bonded to the second functional group; and
forming an interfacial layer interposed between the first insulating layer and the second insulating layer by bonding the first self-assembled monolayer and the second self-assembled monolayer.

19. The method of claim 18, wherein the first self-assembled monolayer comprises:
the first head group;
a first terminal group; and
a first hydrocarbon chain connecting the head group and the first terminal group,
wherein
the second self-assembled monolayer comprises:
the second head group;
a second terminal group; and
a second hydrocarbon chain connecting the head group and the second terminal group, and
in the forming of the interfacial layer, the first terminal group and the second terminal group are bonded to each other.

20. The method of claim 18, wherein in the performing of the first surface treatment process, a first oxide film is formed on a first surface of the first pad,
in the forming of the first self-assembled monolayer, a first source material of the first self-assembled monolayer reacts with the first oxide film to remove the first oxide film,
in the performing of the second surface treatment process, a second oxide film is formed on a second surface of the second pad, and
in the forming of the second self-assembled monolayer, a second source material of the second self-assembled monolayer reacts with the second oxide film to remove the second oxide film.
